(19) United States
(12) Patent Application Publication
(10) Pub. No.: US 2026/0282928 A1
(43) Pub. Date: Sep. 17, 2026

(54) OPTICAL PACKAGE MODULE AND MANUFACTURING METHOD THEREOF

(71) Applicant: SILICONWARE PRECISION INDUSTRIES CO., LTD., Taichung City (TW)

(72) Inventors: Yi-Chun LAI, Taichung City (TW); Hsuan-Jen WANG, Taichung City (TW); Hao-Cheng WANG, Taichung City (TW); Hung-Hsiang FANG, Taichung City (TW); Ying-Chi CHI, Taichung City (TW)

(73) Assignee: SILICONWARE PRECISION INDUSTRIES CO., LTD., Taichung City (TW)

(21) Appl. No.: 19/297,659

(22) Filed: Aug. 12, 2025

(30) Foreign Application Priority Data
Mar. 13, 2025 (TW) 114109380

(51) Int. Cl. H01L 23/552; H01L 23/00; H01L 23/31; H01L 25/16

(52) U.S. Cl. CPC H10W 42/20; H10W 74/134; H10W 90/00; H10W 72/221; H10W 72/227; H10W 72/242

(57) ABSTRACT

Provided are an optical package module and a manufacturing method thereof. A photonic component is disposed on an electronic module including an electronic component. The photonic component is electrically connected to the electronic component to process optical signals. An electromagnetic shielding layer is formed on the electronic module and covers the photonic component. The electromagnetic shielding layer is filled with a plurality of magnetic metal particles to provide the photonic component with resistance to electromagnetic waves.

### BACKGROUND

### 1. Technical Field

The present disclosure relates to a package structure, and more particularly, to an optical package module and a manufacturing method thereof.

### 2. Description of Related Art

With the vigorous development of the electronics industry and communication technology, the current fifth-generation (5G) communication technology has been applied to various fields such as Internet of Things (IoT), Industrial Internet of Things (IIoT), cloud, artificial intelligence (AI), autonomous car, and medical care, as well as all levels of these fields. With the expansion of the application fields and levels of the 5G communication technology, an extremely large amount of data is generated that needs to be transmitted, processed, and stored efficiently. Thus, the industry has begun to enter the generation of optical communication, using “light” instead of “electricity” as the carrier of data transmission.

With the development of optical communication technology, silicon photonic components and related technologies have begun to receive attention. Existing semiconductor package applying silicon photonic technology includes an electronic chip formed in a package structure and a photonic chip connected to the package structure, wherein a side end of the photonic chip is connected to an optical fiber, so that optical signals can be transmitted to the photonic chip for communication.

However, the aforementioned semiconductor package primarily relies on the photonic chip for signal transmission, and problems with reduced signal transmission may arise if it is affected by electromagnetic wave interference.

Therefore, how to overcome the aforementioned problems of the prior art has become as urgent issue to be solved.

### SUMMARY

In view of the aforementioned shortcomings of the prior art, the present disclosure provides an optical package module, which comprises: an electronic module; a photonic component disposed on and electrically connected to the electronic module; and an electromagnetic shielding layer formed on the electronic module and covering the photonic component.

The present disclosure further provides a method of manufacturing an optical package module, and the method comprises: providing an electronic module; disposing a photonic component on the electronic module and electrically connecting the photonic component to the electronic module; and forming an electromagnetic shielding layer on the electronic module to cover the photonic component.

In the aforementioned optical package module and method, the photonic component is a photonic integrated circuit.

In the aforementioned optical package module and method, the electronic module comprises an electronic component electrically connected to the photonic component. The electronic component is an electronic integrated circuit.

In the aforementioned optical package module and method, the electronic module comprises a first circuit structure, an electronic component disposed on the first circuit structure, a plurality of conductive pillars disposed on the first circuit structure, an encapsulation layer encapsulating the electronic component and the plurality of conductive pillars, and a second circuit structure disposed on the encapsulation layer. The first circuit structure and the second circuit structure are electrically connected to each other via the plurality of conductive pillars. The electronic component and the photonic component are electrically connected to each other via the second circuit structure.

In the aforementioned optical package module and method, the electromagnetic shielding layer is filled with a plurality of magnetic metal particles. The plurality of magnetic metal particles are oxides of chromium, iron, cobalt, or nickel.

It can be seen from the above that, in the optical package module and the manufacturing method thereof of the present disclosure, a photonic component is disposed on an electronic module including an electronic component, the photonic component is electrically connected to the electronic component to process optical signals, and an electromagnetic shielding layer is formed on the electronic module and covers the photonic component, wherein the electromagnetic shielding layer is filled with a plurality of magnetic metal particles to provide the photonic component with resistance to electromagnetic waves (shielding effect), preventing the photonic component from being interfered with by electromagnetic waves, which could lead to reduced signal transmission. Additionally, the mechanical strength of the photonic component can be enhanced by the electromagnetic shielding layer covering the photonic component.

### BRIEF DESCRIPTION OF THE DRAWINGS

FIG. 1 to FIG. 5 are schematic cross-sectional views illustrating a method of manufacturing an optical package module according to the present disclosure.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “under,” “a,” “one,” “first,” “second,” and the like are for clear explanation rather than limiting the practicable scope of the present disclosure, and thus, alterations or adjustments of the relative relationships thereof without essentially altering the technical contents should still be considered in the practicable scope of the present disclosure.

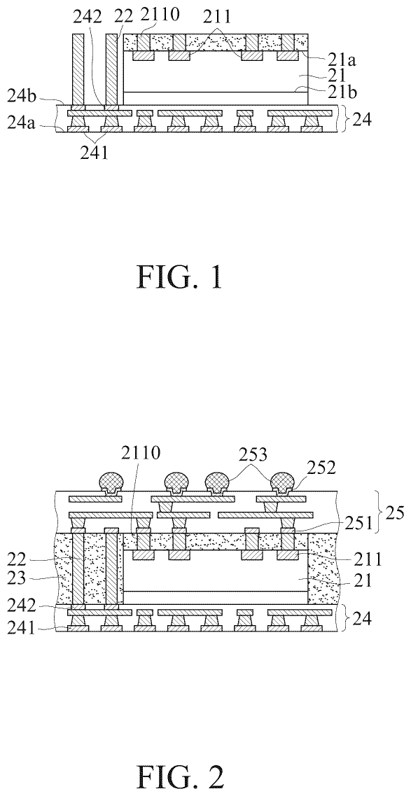

FIG. 1 to FIG. 5 are schematic cross-sectional views illustrating a method of manufacturing an optical package module 2 according to the present disclosure.

As shown in FIG. 1, at least one electronic component 21 is bonded to a first circuit structure 24.

The electronic component 21 has an active surface 21a and an inactive surface 21b opposite to the active surface 21a, and the first circuit structure 24 has a first surface 24a and a second surface 24b opposite to the first surface 24a, wherein the electronic component 21 is connected to the second surface 24b of the first circuit structure 24 via the inactive surface 21b.

The active surface 21a of the electronic component 21 has a plurality of connection pads 211, the first surface 24a of the first circuit structure 24 has a plurality of connection pads 241, and the second surface 24b of the first circuit structure 24 has a plurality of connection pads 242. A plurality of conductive blocks 2110 are disposed on the plurality of connection pads 211 of the electronic component 21, and a plurality of conductive pillars 22 are formed on the plurality of connection pads 242 of the second surface 24b of the first circuit structure 24.

In one embodiment, the electronic component 21 may be an active element, a passive element, or a combination of the active element and the passive element. In one embodiment, the electronic component 21 is an electronic integrated circuit (EIC).

As shown in FIG. 2, an encapsulation layer 23 is formed on the second surface 24b of the first circuit structure 24 and encapsulates the electronic component 21 and the plurality of conductive pillars 22, so that a top surface of the encapsulation layer 23 is coplanar with top ends of the plurality of conductive pillars 22 and top ends of the plurality of conductive blocks 2110, such that the top ends of the plurality of conductive pillars 22 and the top ends of the plurality of conductive blocks 2110 are exposed from the top surface of the encapsulation layer 23.

The encapsulation layer 23 is made of polyimide (PI), epoxy molding colloid, epoxy molding compound, or other insulating materials. The encapsulation layer 23 may be formed by molding, lamination, or coating.

Then, a second circuit structure 25 is formed on the top ends of the plurality of conductive pillars 22 and the top surface of the encapsulation layer 23. A bottom surface of the second circuit structure 25 has a plurality of connection pads 251, and a top surface of the second circuit structure 25 has a plurality of connection pads 252. The plurality of connection pads 251 on the bottom surface of the second circuit structure 25 respectively correspond to and are electrically connected to the plurality of conductive pillars 22 and the plurality of conductive blocks 2110. A plurality of conductive bumps 253 such as solder balls are respectively formed on the plurality of connection pads 252 on the top surface of the second circuit structure 25.

The first circuit structure 24 and the second circuit structure 25 each includes at least one insulating layer and at least one circuit layer. The insulating layer can be made of polybenzoxazole (PBO), polyimide (PI), prepreg (PP), or other dielectric materials. The circuit layer can be a redistribution layer (RDL) and can be made of copper or other conductive materials.

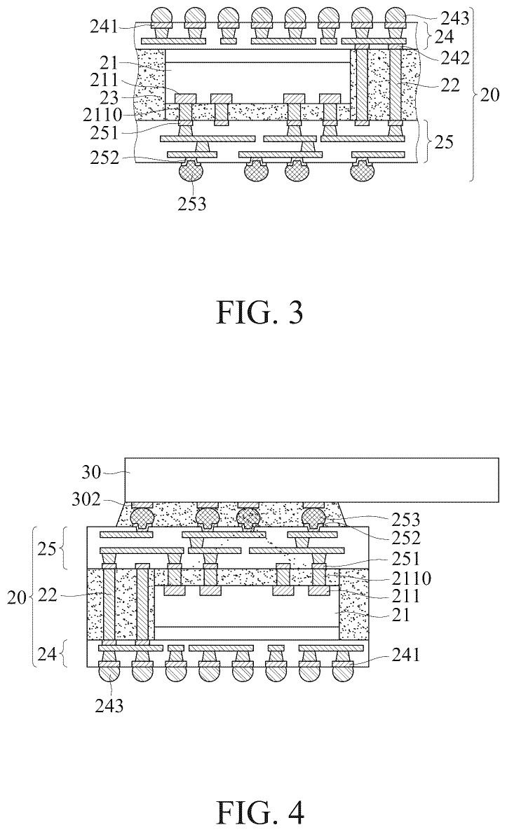

As shown in FIG. 3, a plurality of conductive bumps 243 such as solder balls are respectively formed on the plurality of connection pads 241 disposed on the first surface 24a of the first circuit structure 24. As a result, an electronic module 20 is obtained.

As shown in FIG. 4, a photonic component 30 is disposed on the electronic module 20. The photonic component 30 is electrically connected to the plurality of connection pads 252 and the plurality of conductive bumps 253 disposed on the top surface of the second circuit structure 25 via a plurality of connection pads 302 on a bottom surface of the photonic component 30 in a flip-chip manner. Additionally, the plurality of conductive bumps 253 can be encapsulated by an underfill.

In one embodiment, the photonic component 30 is, for example, a photonic integrated circuit (PIC). The photonic component 30 is used to convert light wave signals into electronic signals to be transmitted to the electronic component 21 in the electronic module 20 for processing or storage.

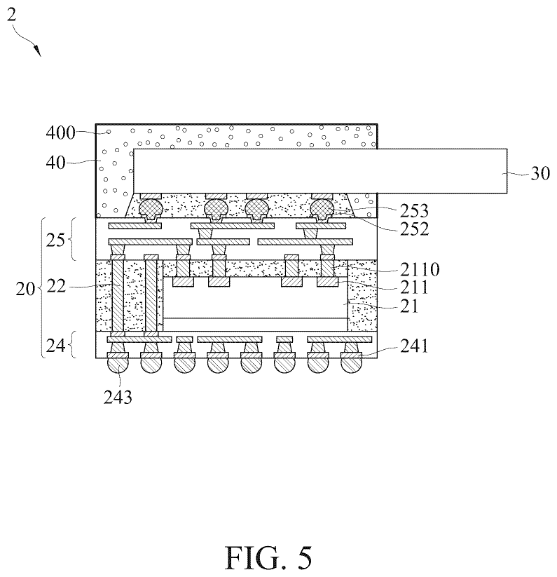

As shown in FIG. 5, a molding process is performed to form an electromagnetic shielding layer 40 covering the photonic component 30 on the electronic module 20. The electromagnetic shielding layer 40 is filled with a plurality of magnetic metal particles 400. The magnetic metal particles 400 can be, for example, oxides of chromium (Cr), iron (Fe), cobalt (Co), or nickel (Ni). As a result, the optical package module 2 of the present disclosure is obtained.

The present disclosure further provides an optical package module 2, which comprises: an electronic module 20; a photonic component 30 disposed on the electronic module 20 and electrically connected to the electronic module 20; and an electromagnetic shielding layer 40 formed on the electronic module 20 and covering the photonic component 30.

In one embodiment, the electronic module 20 includes an electronic component 21 electrically connected to the photonic component 30.

In one embodiment, the electronic module 20 further includes a first circuit structure 24, an electronic component 21 disposed on the first circuit structure 24, a plurality of conductive pillars 22 disposed on the first circuit structure 24, an encapsulation layer 23 encapsulating the electronic component 21 and the plurality of conductive pillars 22, and a second circuit structure 25 disposed on the encapsulation layer 23, wherein the first circuit structure 24 and the second circuit structure 25 can be electrically connected to each other via the plurality of conductive pillars 22.

In one embodiment, the electronic component 21 is electrically connected to the second circuit structure 25, and the photonic component 30 is disposed on the second circuit structure 25 and electrically connected to the second circuit structure 25. That is, the second circuit structure 25 is disposed between the electronic component 21 and the photonic component 30, such that the electronic component 21 and the photonic component 30 are electrically connected to each other via the second circuit structure 25.

In one embodiment, the electronic component 21 is an electronic integrated circuit (EIC).

In one embodiment, the photonic component 30 is a photonic integrated circuit (PIC).

In one embodiment, the electromagnetic shielding layer 40 is filled with a plurality of magnetic metal particles 400, and the plurality of magnetic metal particles 400 are oxides of chromium (Cr), iron (Fe), cobalt (Co), or nickel (Ni).

To sum up, in the optical package module and the manufacturing method thereof of the present disclosure, a photonic component is disposed on an electronic module including an electronic component, the photonic component is electrically connected to the electronic component to process optical signals, and an electromagnetic shielding layer is formed on the electronic module and covers the photonic component, wherein the electromagnetic shielding layer is filled with a plurality of magnetic metal particles to provide the photonic component with resistance to electromagnetic waves (shielding effect), preventing the photonic component from being interfered with by electromagnetic waves, which could lead to reduced signal transmission. Additionally, the mechanical strength of the photonic component can be enhanced by the electromagnetic shielding layer covering the photonic component.

The above embodiments are for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An optical package module, comprising:
an electronic module;
a photonic component disposed on and electrically connected to the electronic module; and
an electromagnetic shielding layer formed on the electronic module and covering the photonic component.

2. The optical package module of claim 1, wherein the photonic component is a photonic integrated circuit.

3. The optical package module of claim 1, wherein the electronic module comprises an electronic component electrically connected to the photonic component.

4. The optical package module of claim 3, wherein the electronic component is an electronic integrated circuit.

5. The optical package module of claim 1, wherein the electronic module comprises a first circuit structure, an electronic component disposed on the first circuit structure, a plurality of conductive pillars disposed on the first circuit structure, an encapsulation layer encapsulating the electronic component and the plurality of conductive pillars, and a second circuit structure disposed on the encapsulation layer.

6. The optical package module of claim 5, wherein the first circuit structure and the second circuit structure are electrically connected to each other via the plurality of conductive pillars.

7. The optical package module of claim 5, wherein the electronic component and the photonic component are electrically connected to each other via the second circuit structure.

8. The optical package module of claim 1, wherein the electromagnetic shielding layer is filled with a plurality of magnetic metal particles.

9. The optical package module of claim 8, wherein the plurality of magnetic metal particles are oxides of chromium, iron, cobalt, or nickel.

10. A method of manufacturing an optical package module, comprising:
providing an electronic module;
disposing a photonic component on the electronic module and electrically connecting the photonic component to the electronic module; and
forming an electromagnetic shielding layer on the electronic module to cover the photonic component.

11. The method of claim 10, wherein the photonic component is a photonic integrated circuit.

12. The method of claim 10, wherein the electronic module comprises an electronic component electrically connected to the photonic component.

13. The method of claim 12, wherein the electronic component is an electronic integrated circuit.

14. The method of claim 10, wherein the electronic module comprises a first circuit structure, an electronic component disposed on the first circuit structure, a plurality of conductive pillars disposed on the first circuit structure, an encapsulation layer encapsulating the electronic component and the plurality of conductive pillars, and a second circuit structure disposed on the encapsulation layer.

15. The method of claim 14, wherein the first circuit structure and the second circuit structure are electrically connected to each other via the plurality of conductive pillars.

16. The method of claim 14, wherein the electronic component and the photonic component are electrically connected to each other via the second circuit structure.

17. The method of claim 10, wherein the electromagnetic shielding layer is filled with a plurality of magnetic metal particles.

18. The method of claim 17, wherein the plurality of magnetic metal particles are oxides of chromium, iron, cobalt, or nickel.
